(19) United States
(12) Patent Application Publication
(10) Pub. No.: US 2022/0306459 A1
(43) Pub. Date: Sep. 29, 2022

(54) METHOD FOR FORMING MICRO CHANNELS IN MOLDED COMPONENTS AND AN ASSOCIATED MICRO-CHANNEL FORMING TOOL

(71) Applicant: Tessy Plastics Corporation, Elbridge, NY (US)

(72) Inventors: Robert Benson, East Syracuse, NY (US); Benjamin Passetti, Weedsport, NY (US)

(73) Assignee: Tessy Plastics Corporation, Elbridge, NY (US)

(21) Appl. No.: 17/704,424

(22) Filed: Mar. 25, 2022

Related U.S. Application Data
(60) Provisional application No. 63/165,847, filed on Mar. 25, 2021.

(51) Int. Cl. B81C 1/00; B29C 59/02; B29C 59/16

(52) U.S. Cl. CPC B81C 1/00071; B81C 1/0046; B29C 59/02; B29C 59/16; B81C 2201/0102; B29C 2791/008; B29L 2031/756

(57) ABSTRACT

A method of forming micro-channels in a plastic surface using a pressing device includes structuring a micro-channel forming tool for the pressing device to include a press end including a press surface that extends along a plane and a micro-channel detail positioned on the press end and extending beyond the plane of the press surface. The micro-channel detail includes a non-critical portion and a critical portion supported by the non-critical portion. The press end of the micro-channel forming tool is driven into the plastic surface at a predetermined force using a pressing device. Ultrasonic vibrations are applied to the micro-channel forming tool for a predetermined amount of time to melt portions of the plastic surface in contact with the pressing surface. The ultrasonic vibrations are removed after the predetermined amount of time has elapsed and the press end is retracted from the plastic surface.

### CROSS-REFERENCE TO RELATED APPLICATION

This application is a non-provisional of, and claims the benefit and priority of U.S. Provisional Application Ser. No. 63/165,847, filed Mar. 25, 2021. The entire contents of said application is incorporated by referenced.

### TECHNOLOGICAL FIELD

This disclosure is generally related to a method of molding plastic components and more specifically a method for forming micro channels in molded plastic components and an associated micro-channel forming tool.

### BACKGROUND

Micro-channels for micro-fluidic movement are used in a variety of fields, especially the healthcare field. These micro-channels are formed in substrate components and may be part of many types of diagnostic testing or “labs on a chip.” However, creating these micro-channels in molded components for micro-fluid movement is a challenging process. This is due to the stringent tolerances the micro-channels must adhere to as well as the complex geometries and surface finishes that are required in the end device. The core pins required in order to mold these complex micro-channels are extremely difficult to manufacture using the equipment and methods currently available. For example, the multi-cavity mold tools required to mold such complex micro-channels must have multiple critical detailed core pins that are manufactured to be identical to each other.

Other methods employed to create micro-channels include a basic coining process where a die is used to press the desired microchannel design into the molded plastic component. However, when utilizing a basic coining process on plastic components, and more specifically molded plastic components, the micro-channel details stamped or pressed into the plastic component shrinks or becomes somewhat distorted after the pressing process due to material memory. Consequently, the resulting micro-channels do not maintain the stringent tolerances and the complex geometry of the micro-channel details of the die. This basic coining process further adds stress to the base component material around the coined geometry. Still another methods use laser cutting to form micro-channels in molded components, however such a process is time consuming and requires specialized laser cutting/etching equipment. This equipment is expensive to purchase and operate, which will increase the cost of each unit produced.

These are just some of the problems associated with creating micro-channels for micro-fluidic movement in molded components.

### SUMMARY

In an embodiment, a method of forming micro-channels uses ultrasonic welding equipment to create a micro-channel forming tool with geometry corresponding to the desired micro-channel. The tool may comprise an extended length and/or height to account for process variations as well as welder optimized ultrasonic geometry. The micro-channel forming tool may be comprised of one or more different materials and used in conjunction with ultrasonic vibration to form micro-channels in a molded component. The ultrasonic vibrations act to heat the base material (e.g. plastic material) around the micro-channel details of the micro-channel forming tool, which enables the base material to reach its melting temperature and form around the tool details.

A method of forming one or more micro-channels in a molded component comprises forming a micro-channel forming tool for a press device, wherein the micro-channel forming tool comprises a micro-channel detail. The molded component is positioned relative to the micro-channel forming tool and the micro-channel forming tool is contacted with or otherwise pressed against the molded component with a predetermined amount of force. The predetermined amount of force exerted on the micro-channel forming tool presses the micro-channel detail into the molded component. Ultrasonic vibrations arc applied at a predetermined rate to the molded component to melt the material of the molded component around the micro-channel detail. The ultrasonic vibrations are stopped after a predetermined amount of time and the micro-channel forming tool is retracted from the molded component thereby removing the micro-channel detail and leaving a micro-channel impression on the molded component. The depth, force, and vibrations may be easily altered to adjust the channel depth or flow rate of the given channel. The disclosed method further produces a channel surface finish that resembles the surface finish of the micro-channel forming tool. For example, a polished tool will result in a polished or highly finished channel surface. The channel surface finish is a characteristic of the micro-channel which may affect flow rate of material through the channel.

In an embodiment, the ultrasonic vibrations are applied concurrently with the pressing of the micro-channel detail into the molded component. In an embodiment, the micro-channel detail may be continuous, however in other embodiments, the micro-channel detail may comprise one or more breaks. In an embodiment, the micro-channel forming tool is configured to form at least two micro-channels in the molded component.

A method of forming micro-channels in a plastic surface using a pressing device includes structuring a micro-channel forming tool for the pressing device to comprise a press end including a press surface that extends along a plane and a micro-channel detail positioned on the press end and extending beyond the plane of the press surface. The micro-channel detail includes a non-critical portion coupled to the press surface and extending beyond the plane to an interface and a critical portion extending from the interface and supported by the non-critical portion. The micro-channel forming tool is installed onto the pressing device and the press end is driven into the plastic surface at a predetermined force using a pressing device. Ultrasonic vibrations are then applied to the micro-channel forming tool at a predetermine frequency for a predetermined amount of time. The ultrasonic vibrations arc removed after the predetermined amount of time has elapsed and the press end of the micro-channel forming tool is retracted from the plastic surface. The ultrasonic vibrations melt portions of the plastic surface in contact with the pressing surface of the micro-channel forming tool.

In an embodiment, the method further includes forming the critical portion from a first material and forming the non-critical portion from a second material. In another embodiment, the first material is different from the second material. In an embodiment, the method further includes driving the press end of the micro-channel forming tool into the plastic surface comprises driving the at least a portion of the critical portion into the plastic surface. In an embodiment, the micro-channel detail comprises one or more highly polished surfaces. In an embodiment, the press surface comprises a textured surface extending along the plane of the press surface.

An embodiment of a micro-channel forming tool for attaching to a pressing device includes a first end configured to removably couple to pressing device and a second end including a press surface that extends along a plane. The second end defines a micro-channel detail formed on the press end and extending beyond the plane of the press surface. The micro-channel detail includes a non-critical portion coupled to the press surface and extending beyond the plane to an interface and a critical portion extending from the interface and supported by the non-critical portion.

In an embodiment, the critical portion is comprised of a first material and the non-critical portion is comprised of a second material. In an embodiment, the first material is different from the second material. In an embodiment, the first end defines one or more surface features. In an embodiment, the micro-channel detail includes one or more highly polished surfaces. In an embodiment, the press surface comprises a textured surface extending along the plane of the press surface.

Another embodiment of a method of forming micro-channels in a plastic surface using a pressing device comprises structuring a micro-channel forming tool for the pressing device to comprise a press end including a press surface that extends along a plane and a micro-channel detail positioned on the press end and extending beyond the plane of the press surface. The micro-channel forming tool is installed onto the pressing device and the press end is driven into the plastic surface at a predetermined force using a pressing device. Ultrasonic vibrations are applied to the micro-channel forming tool at a predetermine frequency for a predetermined amount of time. The ultrasonic vibrations are removed after the predetermined amount of time has elapsed and the press end of the micro-channel forming tool is retracted from the plastic surface. The ultrasonic vibrations melt portions of the plastic surface in contact with the pressing surface of the micro-channel forming tool.

### BRIEF DESCRIPTION OF DRAWINGS

A more particular description of the invention briefly summarized above may be had by reference to the embodiments, some of which arc illustrated in the accompanying drawings. It is to be noted, however, that the appended drawings illustrate only typical embodiments of this invention and are therefore not to be considered limiting of its scope, for the invention may admit to other equally effective embodiments. Thus, for further understanding of the nature and objects of the invention, references can be made to the following detailed description, read in connection with the drawings in which:

FIG. 1A illustrates a top perspective view of an embodiment of a molded plastic component;

FIG. 1B illustrates a top perspective view of an embodiment of a core pin used to create the molded plastic component of FIG. 1A;

FIG. 1C illustrates a bottom plan view of an embodiment of a core pin used to create the molded plastic component of FIG. 1A;

FIG. 2 illustrates a top perspective view of an embodiment of a micro-channel forming tool with an embodiment of a micro-channel detail;

FIG. 3A illustrates a cross-sectional view of the embodiment of the micro-channel detail if FIG. 2 along A-A;

FIG. 3B illustrates a close-up view of an embodiment of the micro-channel forming tool;

FIG. 3C illustrates a perspective view of an embodiment of a sonotrode configured to removably couple to a micro-channel forming tool;

FIG. 3D illustrates a perspective view of an embodiment of the micro-channel forming tool before installation onto the sonotrode;

FIG. 4 illustrates a magnified top plan view of an embodiment of a micro-channel forming tool with an embodiment of a micro-channel detail;

FIG. 5A illustrates a partial magnified view of an embodiment of a micro-channel detail;

FIG. 5B illustrates a perspective view of an embodiment of a micro-channel forming tool having a highly polished finish;

FIG. 6 illustrates a top plan view of an unpolished embodiment of the micro-channel forming tool with a micro-channel detail;

FIG. 7A illustrates a top perspective view of an embodiment of a micro-channel formed into an embodiment of the molded component;

FIG. 7B illustrates a partial close-up view of the embodiment of FIG. 7A;

FIG. 8 illustrates a top plan view of an embodiment of a micro-channel formed into an embodiment of the molded component;

FIG. 9A illustrates a top perspective view of another embodiment of a micro-channel formed into an embodiment of the molded component;

FIG. 9B illustrates a partial close-up view of the embodiment of FIG. 9A;

FIG. 10 illustrates a top plan view of an embodiment of a micro-channel formed into an embodiment of the molded component with waves bounding sides of the micro-channel;

FIG. 10A is a cross sectional view of the embodiment of the micro-channel of FIG. 10 take along B-B;

FIGS. 11A-D illustrate material waves formed during micro-channel formation showing an increase on wave formation at eh sides of the micro-channel as the applied energy increases;

FIGS. 12A-D illustrate an example of micro-channel formation under conditions that do not form material waves and having various surface finishes; and

FIG. 13 illustrates an enlarged perspective view of an embodiment of a lab-on-a-chip device comprising a plurality of micro-channels.

### DETAILED DESCRIPTION

The following discussion relates to various embodiments of a method of forming micro channels in molded components and a micro-channel forming tool. It will be understood that the herein described versions are examples that embody certain inventive concepts as detailed herein. To that end, other variations and modifications will be readily apparent to those of sufficient skill. In addition, certain terms are used throughout this discussion in order to provide a suitable frame of reference with regard to the accompanying drawings. These terms such as “upper”, “lower”, “forward”, “rearward”, “interior”, “exterior”, “front”, “back”, “top”, “bottom”, “inner”, “outer”, “first”, “second”, and the like arc not intended to limit these concepts, except where so specifically indicated. The terms “about” or “approximately” as used herein may refer to a range of 80%-125% of the claimed or disclosed value. With regard to the drawings, their purpose is to depict salient features of the method of forming micro channels in molded components and an associated micro-channel forming tool and are not specifically provided to scale.

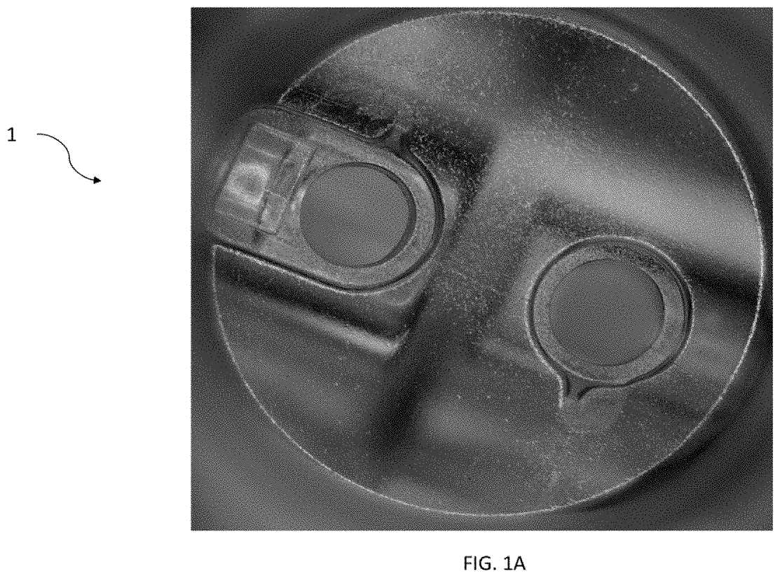

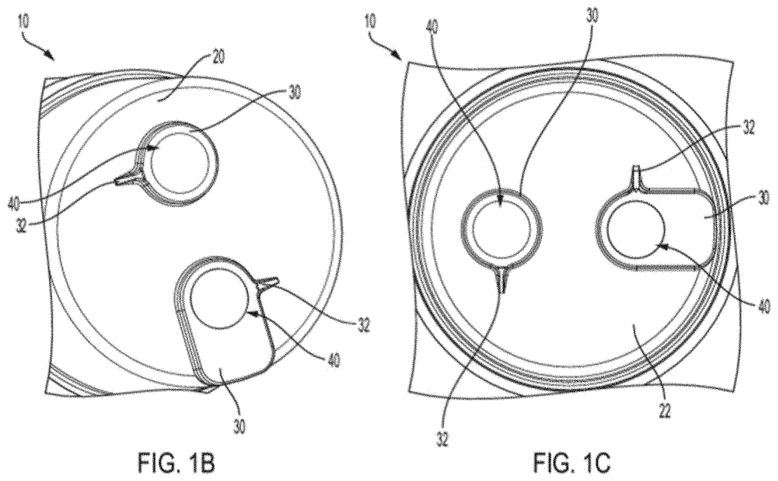

FIG. 1A is an example of a mold core pin 1 that may be used to form a molded component 10. The mold core pin 1 as shown is used to form the embodiment of the molded component 10 show in FIGS. 1B-C. The molded plastic component 10 may be used as part of a micro-fluid assembly 50 for a medical device, medical testing and/or medical diagnostic device. While the forging description is focused on these embodiments of the molded component, it is envisioned that the molded component 10 may be any configuration suitable for the intended purpose of the end product and is not limited to medical device, medical testing and/or medical diagnostic devices. The molded component 10 may generally comprise a flat testing surface 20 defining one or more recesses 30, reservoirs or openings 40 configured to accept an inserted component or a combination thereof. As shown, a channel entrance 32 and a channel exit 33 may partially extend from the recesses 30. In another embodiment, more than one channel entrance and exit may extend from the recesses 30 to provide ingress and egress to multiple micro-channel complexes. One skilled in the art would realize that the molded plastic component 10 or components may have a variety of shapes and molded features depending on the intended use. Moreover, the molded components 10 may be comprised of one or more different plastics and formed using any known molding technique including injection molding. The plastics used to form the molded component 10 may include thermoplastics like polycarbonates and polyethylene terephthalate (PET), clear plastics such as acrylic, and amorphous polymers, such as cyclic olefin copolymer (COC.)

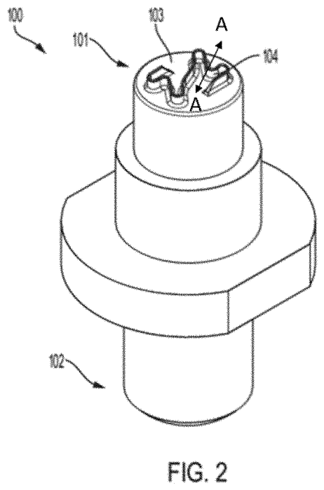

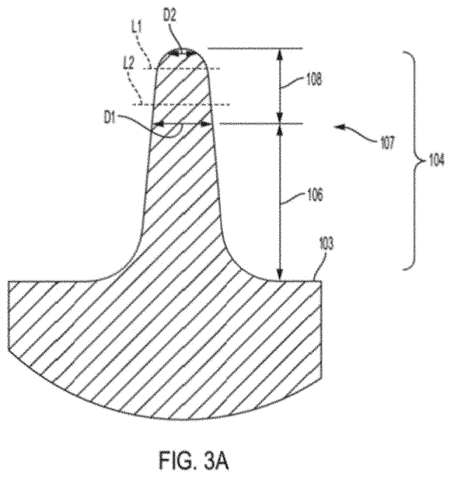

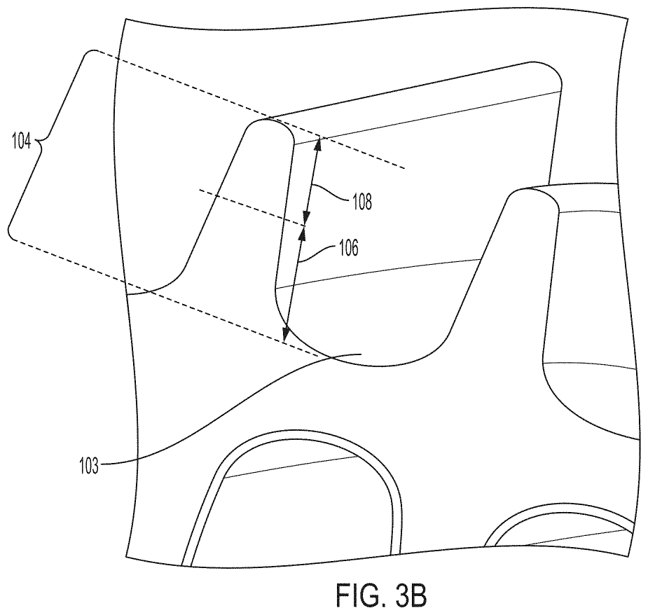

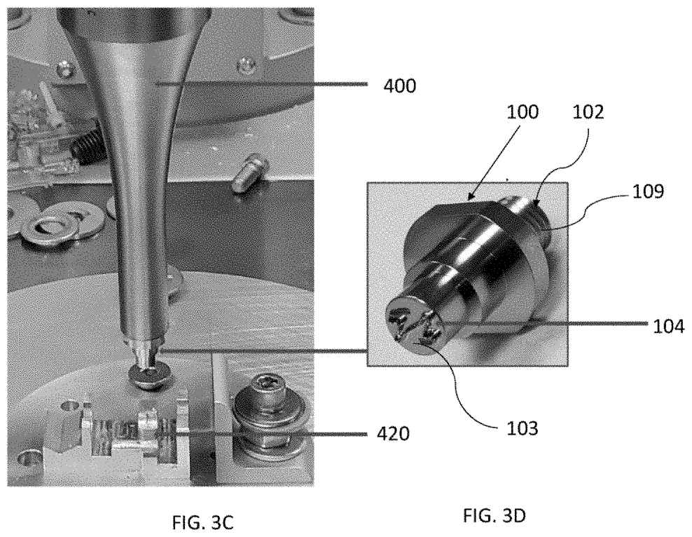

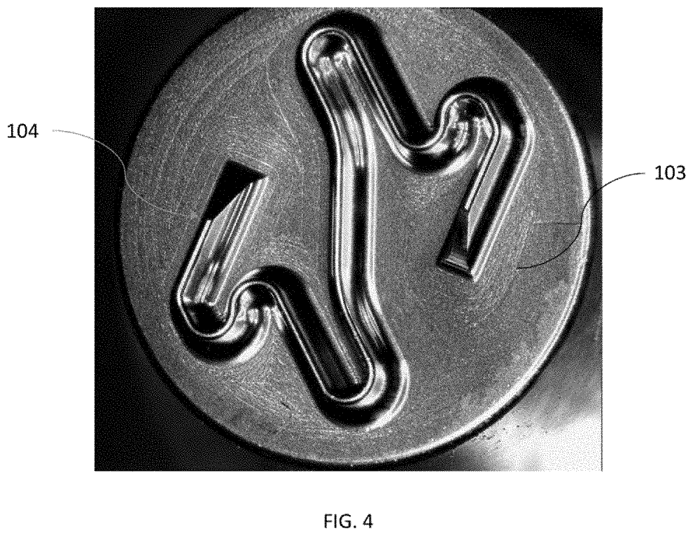

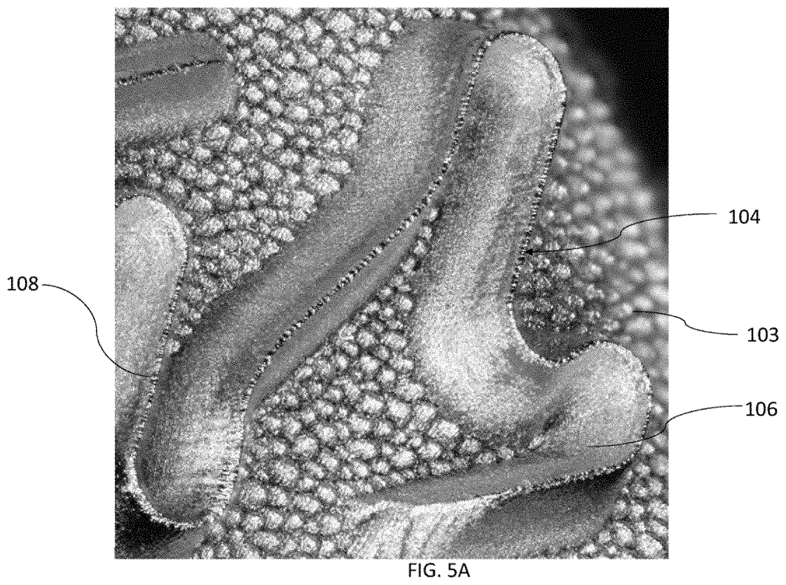

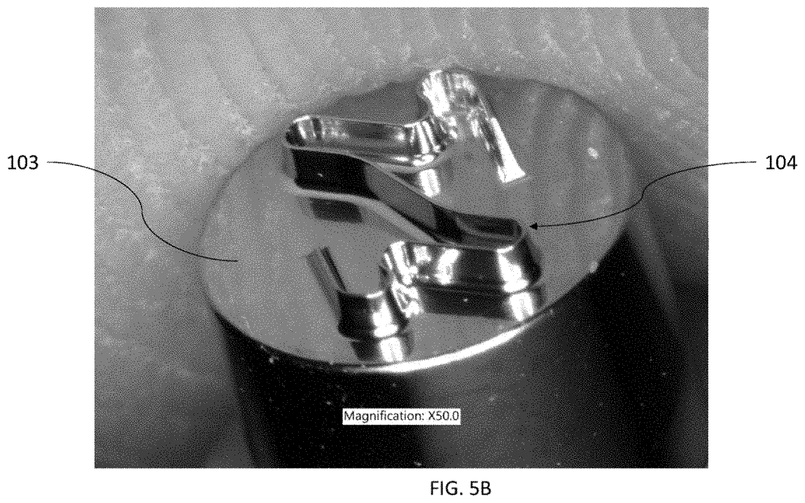

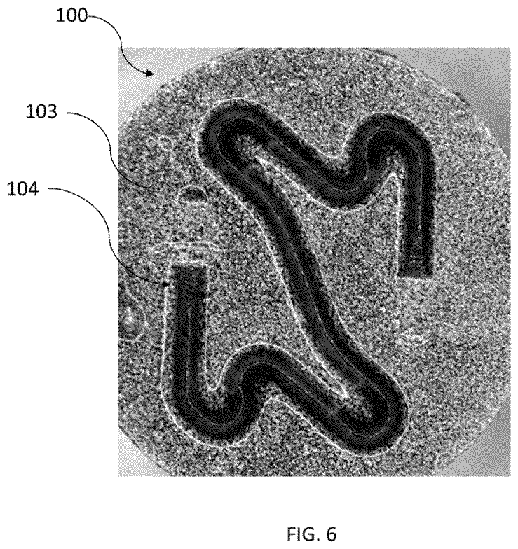

A micro-channel forming tool (“tool”) 100 generally comprises a pressing end 101 and an opposing end 102. Referring to FIGS. 2-6, the opposing end 102 may be configured to be inserted into and secured to a press machine. The opposing end 102 may have one or more surface features 109 or define one or more openings, bores, recesses or any other feature necessary to aid in securing the opposing end 102 to the press machine. The press end 101 may generally comprise a press end surface 103 that extends along a plane P and a micro-channel detail 104. The micro-channel detail 104 extends above the plane of the press end surface 103 and includes a non-critical portion 106 and a critical portion 108 (see FIG. 3A). As shown in FIGS. 3A and 3B, the non-critical portion 106 and the critical portion 108 meet at an interface 107. The critical portion 108 is the portion of the micro-channel detail 104 that will form the micro-channel in the molded component 10 and is manufactured to exact specifications. The non-critical portion 106 of the micro-channel detail 104 extends from the press end surface 103 and supports the critical portion 108. The non-critical portion 106 is not involved in the micro-channel formation and therefore does not need to meet stringent specifications. Therefore, the non-critical portion 106 may be comprised from a different material than the critical portion 108 in order to increase the ease and decrease the cost of manufacturing the micro-channel forming tool 100.

The micro-channel forming tool 100 may be manufactured using any known additive, subtractive or other manufacturing process. Accordingly, the geometry and pattern of the micro-channel detail 104 may vary between each micro-channel forming tool 100 depending on the desired capacity and flow characteristics within the micro-channels. As shown in FIG. 3A, the micro-channel detail 104 comprises a first diameter D1 at the interface 107 and a second diameter D2 at a distal end that is part of the critical portion 108. As shown, D1 is greater than D2. The non-critical portion 106 may comprise a diameter at the interface 107 that is the same as D2 and may increase towards the press end surface 103. The critical portion 108 may be shaped to comprise a plurality of diameters between the interface 107 and the distal end where each of the plurality of diameters decreases as they approach the distal end of the critical portion 108.

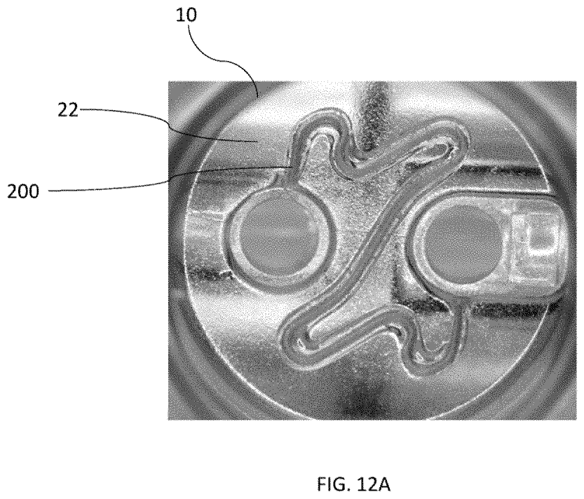

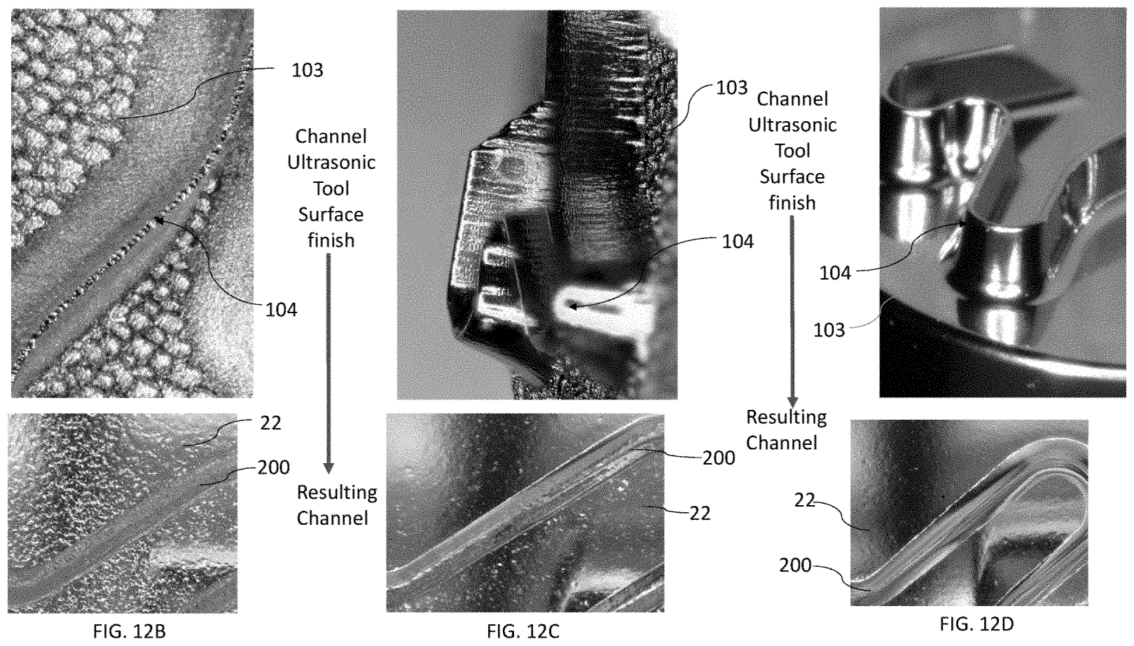

Once the molded component 10 is formed it is then positioned within a press device fitted with the micro-channel forming tool 100. The pressing device drives at least a portion of the critical portion 108 into the molded component 10 using a predetermined force, which can be set using controls of the pressing device. As shown, the tool 100 is pressed into the underside 22 of the flat test surface 20 to form the micro-channel 200 (FIG. 12A). Ultrasonic vibrations are then applied to the plastic component via the tool, which act to heat the material of the molded component 10 proximate the tool 100 to its melting point such that it forms around the micro-channel detail 104 and creates an edge transition to the flat undersurface 22 of the molded component 10. In the example illustrated, the tool 100 is configured to imprint a micro-channel to connect the channel entrance 32 and the channel exit 33 of the molded component 10. After a predetermined amount of time, the ultrasonic vibrations are stopped and the tool 100 is removed. The use of ultrasonic vibrations to melt surrounding material acts to prevent distortion of the micro-channel 200 (FIG. 12A) due to material memory.

Referring to FIG. 3B, the micro-channel forming tool 100 may be configured to be removably coupled to a sonotrode 400. The molded plastic component 10 may be placed in or held in a specific position by a nest 420 or other such restraining device. The nest 420 may be coupled to the sonotrode 400 but may be configured to be adjusted independent of the sonotrode 400. This embodiment of the sonotrode 400 is configured to exert a pressing force to imprint the micro-channel detail onto the retained molded component 10. Once the critical portion 106 is embedded into the molded component, the sonotrode 400 may be controlled to apply the desired level of ultrasonic vibration to melt the plastic material proximate to the tool 100.

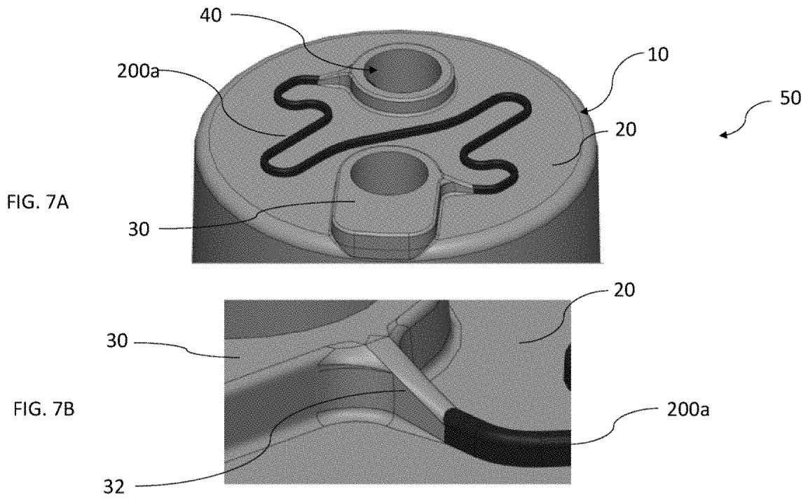

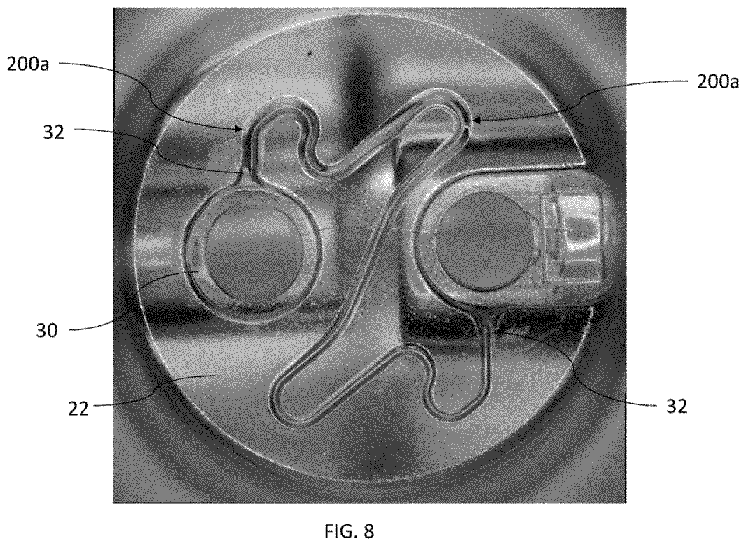

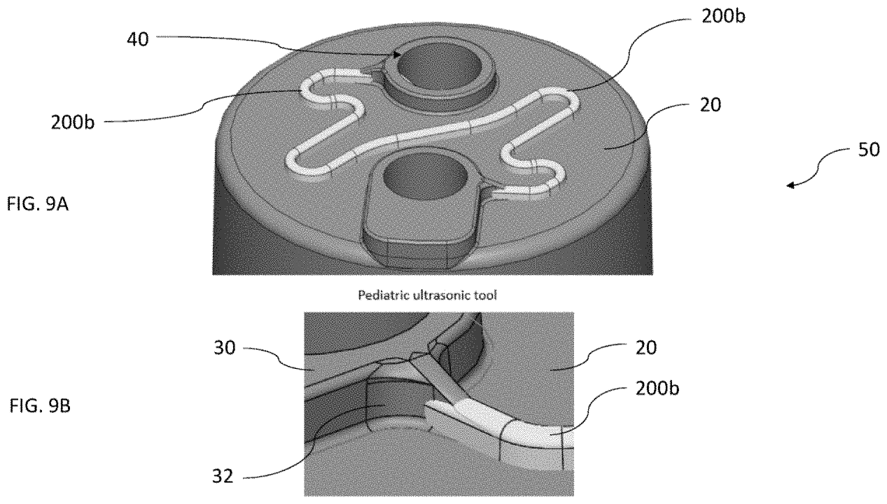

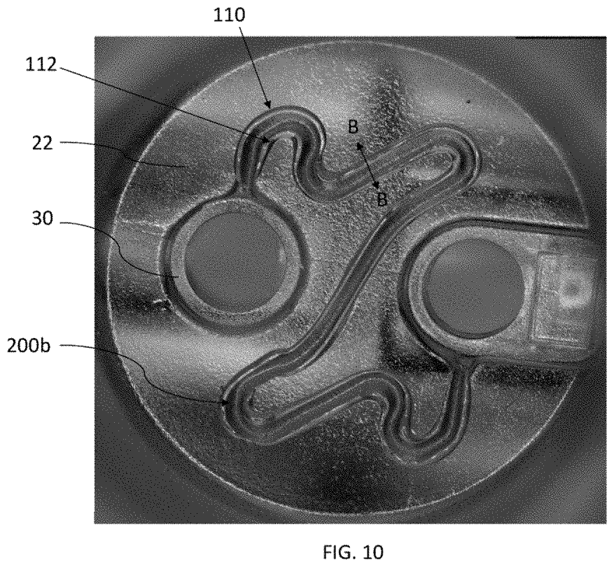

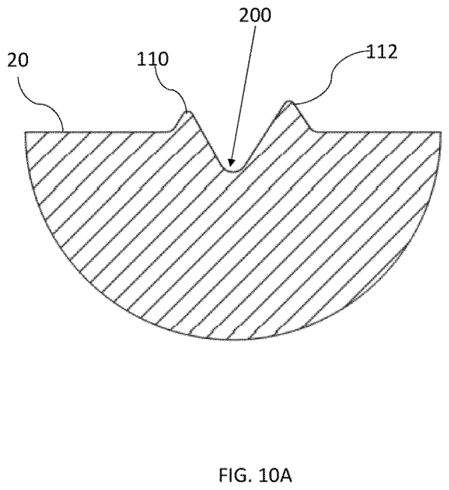

The pressing force exerted by the press device may be adjusted as desired. Similarly, the level of ultrasonic vibrations may be adjusted as desired. As a result, the geometry and flow characteristics of the micro-channel 200 (FIG. 12A) may be changed depending on the amount of force and level of ultrasonic vibration used to drive the tool 100 into underside 22 of the testing surface 20 of the molded component 10. As shown in FIGS. 7A-8 for example, a lower driving force may result in the tool 100 being pressed into the molded component 10 such that micro-channel detail 104 is pressed into the molded component 10 up to a level L1 (FIG. 3) which results in a shallower, yet narrower micro-channel 200a as compared to that produced using a greater pressing force. Applying a greater pressing force may enable the micro-channel detail 104 to be pressed into the molded component 10 to a level L2 (FIG. 3) creating a micro-channel 200b that has a wider and deeper micro-channel 200b as shown in FIGS. 9A-10. In an embodiment, the tool 100 may be pressed to a point just below the interface 107 such that all or approximately all of the critical portion 108 is pressed into the molded component 10. In this manner, the geometry and flow characteristics of the micro-channels may be predictably and accurately reproduced in a cost-effective manner when manufacturing a plurality components.

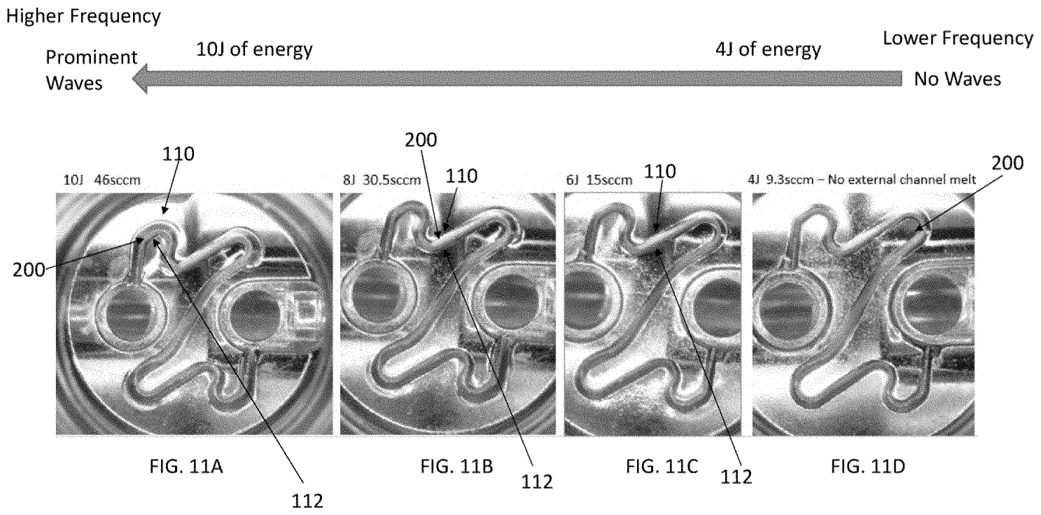

Overall, there is a fine balance of vertical pressing force and ultrasonic vibration energy applied to the surface of the component 10. Referring to the examples illustrated in FIGS. 10, 10A and 11A-D, the pressing force may, for example, be reduced if the ultrasonic vibrations are increased but there is a balance threshold. Applying high levels of ultrasonic vibration at the incorrect time during the process cycle will cause “waves” 110, 112 of material to form. As shown in FIGS. 10 and 10A, the formation of waves 110, 112 occur as a first wave 110 and a second wave 112 positioned such that the micro-channel 200, 200b is located between the waves 110, 112. Adjusting the energy level of ultrasonic vibrations, the frequency of the vibrations and/or the depth of the vibrations (depth that the micro-channel forming tool penetrates into the surface 20) enables the formation of waves 110, 112 to be closely controlled in order to meet the product specifications of volume, flow rate, etc . . . In some embodiments, the first wave 110 projects farther from the surface 20 than the second wave 112 (or vice-versa). FIGS. 11A-11D show the progression of wave 110, 112 formation as the energy level of ultrasonic vibrations applied is increased. The formation of waves 110, 112 can further be eliminated in instances where the final product dictates. The inventors have found that, when using molded components comprising polycarbonate, the micro-channel forming process should start by applying the pressing force followed by light ultrasonic vibration to melt or reflow and stress relieve the material area around the channel geometry. This prevents distortion of the micro-channel resulting from material memory and provides a unstressed channel with a surface finish that compliments the tool finish as shown, for example, in FIGS. 12A-D. FIG. 12A shows an example of a micro-channel formed using a lightly polished micro-channel forming tool. FIG. 12B shows an example of a media blasted micro-channel forming tool, FIG. 12C shows another example of a lightly polished micro-channel forming tool, and FIG. 12D shows an example of an electro-polished micro-channel forming tool. These figures are illustrative of the variety of finishes that are capable of being incorporated into the finished micro-channels. As can be seen, the finish on the micro-channel forming tool 100 may vary from a rough, media blasted surface to a smooth, electro-polish. The finish on the micro-channels affects the flow rate of fluid through the micro-channels. In other words, the smoother the finish on the micro-channel, the faster the fluid will flow through said micro-channel. Alternatively, micro-channels with a rough finish will experience a slower flow rate. The disclosed method enables this finish to be reproduced on the molded component 10 during the micro-channel forming process.

Of course, the use of tools 100 with differently shaped micro-channel details may yield micro-channels that are proportioned differently than those formed using the embodiment of the tool 100 with the embodiment of the micro-channel detail 104 discussed above. For example, the depth of the micro-channel(s) may vary depending on the micro-channel forming tool that is used. In some embodiments, the critical portion 108 of the micro-channel detail 104 may be configured to produce a micro-channel 200 with an inconsistent or varying depth and/or width.

In an embodiment, the micro-channels 200, 200a, 200b may be formed in the molded component 10 as part of a manufacturing assembly line where molded components 10 are formed at a first station and are transported to a second station comprising a press fitted with the micro-channel forming tool 100. This method of manufacturing may be automatic with each molded component 10 being aligned at the press device with the aid of one or more optical sensors and/or lasers. In another embodiment, the molded components 10 are aligned at the press device using a jig or other similar alignment aid.

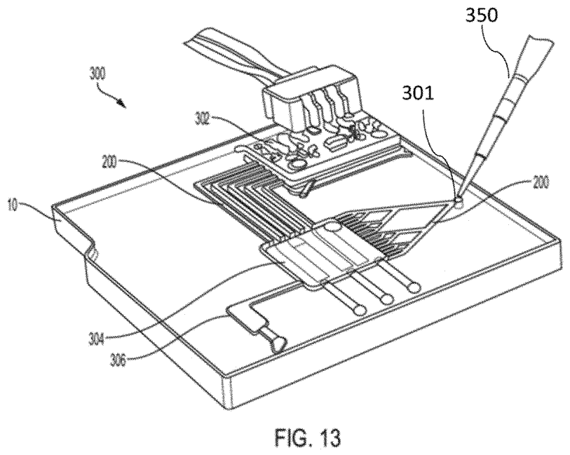

Referring to FIG. 13, the molded component 10 may form part of a lab-on-a-chip device 300 comprising one or more micro-channels 200 used to transport a small amount of fluid to and from one or more constituents 302, 304, 306 of the chip device 300 such as sensors, incubation bays, filters, drains, etc . . . As shown, a small amount of fluid may be applied to a first well 301 using a micro-pipette 350 or other dispensing tool/device. In an embodiment of this device 300, the micro-channels 200 may be configured to transport very small fluid volumes that may be on the order of or less than a pico-liter.

In an embodiment, the method may be used to form micro-features in molded components. Said micro-features may be used for purposes of identification, branding, interconnection between components, aesthetics, or other such purposes. The disclosed methods are advantageous for precise and reliable production of micro-channels and micro-channel complexes according to precise specifications.

While the present invention has been particularly shown and described with reference to certain exemplary embodiments, it will be understood by one skilled in the art that various changes in detail may be effected therein without departing from the spirit and scope of the invention that can be supported by the written description and drawings. Further, where exemplary embodiments arc described with reference to a certain number of elements, it will be understood that the exemplary embodiments can be practiced utilizing either less than or more than the certain number of elements.

1. A method of forming micro-channels in a plastic surface using a pressing device, the method comprising:
structuring a micro-channel forming tool for the pressing device to comprise,
a press end including a press surface that extends along a plane,
a micro-channel detail positioned on the press end and extending beyond the plane of the press surface, wherein the micro-channel detail comprises,
a non-critical portion coupled to the press surface and extending beyond the plane to an interface, and
a critical portion extending from the interface and supported by the non-critical portion;
installing the micro-channel forming tool onto the pressing device;
driving the press end of the micro-channel forming tool into the plastic surface at a predetermined force using a pressing device;
applying ultrasonic vibrations to the micro-channel forming tool for a predetermined amount of time;
removing the ultrasonic vibrations after the predetermined amount of time has elapsed; and
retracting the press end of the micro-channel forming tool from the plastic surface,
wherein the ultrasonic vibrations melt portions of the plastic surface in contact with the pressing surface of the micro-channel forming tool.

2. The method according to claim 1, wherein the ultrasonic vibrations are applied at:
a predetermined amount of energy, and
a predetermined frequency

3. The method according to claim 1, further comprising forming the critical portion from a first material and forming the non-critical portion from a second material.

4. The method according to claim 3, wherein the first material is different from the second material.

5. The method according to claim 1, wherein the driving the press end of the micro-channel forming tool into the plastic surface comprises driving the at least a portion of the critical portion into the plastic surface.

6. The method according to claim 1, wherein the micro-channel detail comprises one or more highly polished surfaces.

7. The method according to claim 1, wherein the press surface comprises a textured surface extending along the plane of the press surface.

8. A micro-channel forming tool for attaching to a pressing device, the micro-channel forming tool comprising:
a first end configured to removably couple to pressing device; and
a second end including a press surface that extends along a plane, the second end comprises a micro-channel detail formed on the press end and extending beyond the plane of the press surface, wherein the micro-channel detail comprises,
a non-critical portion coupled to the press surface and extending beyond the plane to an interface, and
a critical portion extending from the interface and supported by the non-critical portion.

9. The micro-channel forming tool according to claim 8, wherein the critical portion is comprised of a first material and the non-critical portion is comprised of a second material.

10. The micro-channel forming tool according to claim 9, wherein the first material is different from the second material.

11. The micro-channel forming tool according to claim 8, wherein the first end defines one or more surface features.

12. The micro-channel forming tool according to claim 8, wherein the micro-channel detail comprises one or more highly polished surfaces.

13. The micro-channel forming tool according to claim 8, wherein the press surface comprises a textured surface extending along the plane of the press surface.

14. A method of forming micro-channels in a plastic surface using a pressing device, the method comprising:
structuring a micro-channel forming tool for the pressing device to comprise,
a press end including a press surface that extends along a plane,
a micro-channel detail positioned on the press end and extending beyond the plane of the press surface;
installing the micro-channel forming tool onto the pressing device;
driving the press end of the micro-channel forming tool into the plastic surface at a predetermined force using a pressing device;
applying ultrasonic vibrations to the micro-channel forming tool at a predetermine frequency for a predetermined amount of time;
removing the ultrasonic vibrations after the predetermined amount of time has elapsed; and
retracting the press end of the micro-channel forming tool from the plastic surface, wherein the ultrasonic vibrations melt portions of the plastic surface in contact with the pressing surface of the micro-channel forming tool.

15. The method according to claim 14, further comprising structuring the micro-channel detail to comprise,
a non-critical portion coupled to the press surface and extending beyond the plane of the pressing surface to an interface, and
a critical portion extending from the interface and supported by the non-critical portion.

16. The method according to claim 15, further comprising forming the critical portion from a first material and forming the non-critical portion from a second material.

17. The method according to claim 16, wherein the first material is different from the second material.

18. The method according to claim 15, wherein the driving the press end of the micro-channel forming tool into the plastic surface comprises driving the at least a portion of the critical portion into the plastic surface.

19. The method according to claim 14, wherein the micro-channel detail comprises one or more highly polished surfaces.

20. The method according to claim 14, wherein the press surface comprises a textured surface extending along the plane of the press surface.
